(19) United States
(12) Patent Application Publication
(10) Pub. No.: US 2011/0030611 A1
(43) Pub. Date: Feb. 10, 2011

(54) METHOD FOR PREPARING POLYCRYSTALS AND SINGLE CRYSTALS OF ZINC OXIDE (ZnO) ON A SEED BY CHEMICALLY ACTIVATED SUBLIMATION AT HIGH TEMPERATURE AND DEVICE FOR CARRYING OUT SAID METHOD

(76) Inventors: Jean-Louis Santailler, Saint Jean De Moirans (FR); Guy Chichignoud, Grenoble (FR); Maurice Couchaud, Izeron (FR)

Correspondence Address: MILES & STOCKBRIDGE PC, 1751 PINNACLE DRIVE, SUITE 500, MCLEAN, VA, 22102-3833, US

(21) Appl. No.: 12/937,063

(22) PCT Filed: Apr. 9, 2009
(86) PCT No.: PCT/EP2009/054334

§ 371 Date: Oct. 8, 2010

(30) Foreign Application Priority Data
Apr. 10, 2008 (FR) 0852418

(51) Int. Cl. C30B 23/06; B05D 5/12; C23C 16/40

(52) U.S. Cl. 117/108; 427/126.3; 118/716

(57) ABSTRACT

A method for preparing polycrystalline or single-crystal zinc oxide ZnO on a seed placed in an enclosure under a controlled atmosphere, by sublimation of a zinc oxide source placed in a crucible inside the enclosure and distant from the seed, by formation of gas species, transport of gas species, condensation of gas species on the seed, recombination of the ZnO at the surface of the seed, growth of polycrystalline or single-crystal ZnO on the seed, and cooling of the polycrystalline or single-crystal ZnO, wherein:
the zinc oxide source is heated by induction at a temperature, a so-called sublimation temperature, from 900 to 1,400° C. under a pressure from 2.10⁻³ atmospheres to 0.9 atmospheres;
CO is generated in situ as a sublimation activator by supplying at least one oxidizing species, or a mixture of an oxidizing species and of at least one inert gas on a solid carbon source placed inside the enclosure;
and control of the stoichiometry of the ZnO is achieved by providing a localized supply with controlled flow rate, for example in an amount from 1 SCCM to 100 SCCM, of at least one oxidizing species or of a mixture of at least one oxidizing species and of at least one inert gas, in the vicinity of a growth interface of the ZnO.

A device for carrying out the method.

### TECHNICAL FIELD

The present invention relates to a method for preparing, forming, polycrystals and single crystals of zinc oxide (ZnO) on a seed, by chemically activated sublimation at high temperature.

The invention further relates to a device for carrying out this method.

More specifically, the present invention relates to a method for preparing polycrystals and single crystals of zinc oxide (ZnO) on a seed by a chemically assisted vapor phase physical transport method (SCVT or [symbol] Sublimation and Chemical Vapor Transport [symbol] ).

The thereby prepared zinc oxide may notably be used, as a substrate or as a detector in various fields such as those of electric, piezoelectric, electro-optical and/or optoelectronic components. In particular, ZnO has a strong potential in the field of light-emitting diodes for lighting applications, and with ZnO it is also possible to produce ultrafast scintillators with a scintillation duration of a few nanoseconds.

The technical field of the invention may therefore be defined as being that of preparing, elaborating, forming polycrystals and single crystals of zinc oxide (ZnO).

Zinc oxide (ZnO) is a semiconductor II-VI with a wide direct bandgap: Eg˜3.35 eV at 300 K. It allows green and blue light emissions as well as especially ultraviolet emissions. Its usual crystallographic structure is of the wurtzite hexagonal type (spatial group P6₃mc). Its lattice parameters are a˜3.25 Å and c˜5.20 Å. It may be used for applications of the light-emitting diode ( [symbol] LED [symbol] ) type, in other words, lighting applications with a solid state semiconductor, as a substrate for homo-epitaxy (n-p ZnO and/or Mg₁₋ₓZnOₓO (0<x<0.2), ZnO and n-p CdO structure) or else as a hetero-substrate for compounds based on gallium nitride (GaN).

The benefit of ZnO lies in the fact that the material may be elaborated in interesting sizes as compared with its competitors such as AlN, GaN, etc. . . .

A significant challenge remains the possibility of controlling p-type doping for microelectronics and of having low defect densities, for example 10²-10³ dislocations/cm².

Generally, crystallogenesis processes for compounds with a wide bandgap, such as ZnO, are very difficult to achieve because they use technologies at very high temperatures, for example 2,000-2,500° C. for SiC and AlN, and/or at high pressures, for example greater than 50 bars for ZnO and GaN, because of the intrinsic properties of these compounds.

Thus, the melting temperature of ZnO is close to 1,980° C. under 1.06 atmospheres and, because of the strong (high) vapor pressure at its melting temperature, it is a material which is very difficult to elaborate from its liquid phase.

However, methods for elaborating bulk (solid) ZnO single crystals notably under strong pressure have been described.

These methods may be classified into four main categories, i.e.: the methods in which the preparation of ZnO is accomplished from liquid ZnO, the methods in which growth is accomplished from a ZnO solution in a liquid solvent, the hydrothermal synthesis methods, and the vapor phase methods among which the methods which use sublimation of ZnO powder.

Methods for preparing single crystals of ZnO from a molten mass have thus been described in document U.S. Pat. No. 5,900,060 [1] which relates to the growth of ZnO in a self-crucible under a strong atmosphere; and document U.S. Pat. No. B2-6,936,101 [2] which relates to the growth of ZnO by a modified Bridgman method, under pressure.

These methods using a molten mass of ZnO under strong (high) pressure remain difficult to apply technically.

An exemplary method for preparing ZnO single crystals using a solvent is given in document U.S. Pat. No. A1-2006/0124051 [3] which relates to a ZnO growth method in a solution at a temperature slightly above 1,060° C. and at atmospheric pressure. The solvent used is for example of the MoO₃, PbO, B₂O₃ type.

The growth methods in a solution today only allow production of ZnO crystals of small volume, of the order of a few mm³.

Presently, hydrothermal methods are the methods which are the most successfully used for preparing bulk ZnO single crystals.

A growth method by hydrothermal synthesis at 350° C. under very strong (high) pressure is for example described in document DE-A1-10 204 003 596 [4].

With the growth conditions of hydrothermal methods, it is possible to obtain crystals with excellent structural quality, with a size greater than 2 inches suitable for a use in microelectronics, and with a thickness for example of 20-30 mm. However, the very slow growth rate generally does not exceed 200 μm per day. The materials elaborated by this method are generally of the n type, the doping originating from contamination by the solvent and especially from deviation from stoichiometry.

Sublimation methods with chemical vapor transport SCVT ( [symbol] Sublimation Chemical Vapor Transport [symbol] ) or with physical vapor transfer PVT ( [symbol] Physical Vapor Transport [symbol] ) are described in documents [5], [6], [7], [8], [9], [10], [11], [12] and [13].

Document U.S. Pat. No. B1-7,279,040 of Oct. 9, 2007 [5]of Wang describes growing ZnO from a solid ZnO source by a high temperature (1,300-1,800° C.) PVT method and under a partial pressure of oxygen varying from 0.01 to 800 torrs, with essentially resistive heating external to the confinement tube. The latter may be in alumina Al₂O₃ or in zirconia stabilized by Y₂O₃. The growth rate may be controlled by means of a neutral gas optionally mixed with oxygen. The configuration of the growth device may be vertical or horizontal and it may contain one seed or two seeds.

Document [6] relates to the growth of ZnO by SCVT ( [symbol] Sublimation and Chemical Vapor Transport [symbol] ) using the residual water present in gases and gas mixtures such as hydrogen, argon, hydrogen and water mixture, as an activator of ZnO sublimation, growth being accomplished at a low temperature 550-600° C.

Document [7] relates to the growth of ZnO crystals by a [symbol] CVT [symbol] method which uses chlorine and carbon as transport agents.

The temperature of the source is from 950° C. to 1,000° C., the crucible is in silica and the duration of the tests ranges up to 800 hours.

At growth temperatures higher than or equal to 1,000° C., the crystals become orange, transparent and conductive. The best crystals with a size of 1 cm³, are obtained with a source temperature of 1,000° C., a temperature difference between the temperature of the source and the growth temperature of 30° C. and a deposition time of 40 days.

Traces of carbon and chlorine (0.053%) are found in the crystals.

Document [8] also describes the growth of ZnO in a quartz crucible by the [symbol] CVT [symbol] method by using carbon as a transport agent at a source temperature from 950 to 1,050° C. The absence of carbon residues in the obtained single crystal shows that it is CO₂ which plays a determining role in the transport of the species.

It is also shown in this document that by proceeding with annealing of the crystals under an oxygenated atmosphere, the red-orangey color of the obtained crystals in document [7] may be eliminated in order to provide colorless and transparent crystals.

Document [9] also describes the growth of ZnO still in a quartz crucible by the [symbol] CVT [symbol] method, by using carbon as a transport agent at a growth temperature of 1,010° C. and a source temperature of 1,016° C.

Document [10] relates to the growth of ZnO in a quartz crucible by [symbol] CVT [symbol] and [symbol] PVT [symbol] methods, wherein sublimation and transport of the vapors are accomplished with the assistance of C, Zn, Fe, Cu and H₂.

Document [11] relates to a method which demonstrates the elaboration of polycrystalline ZnO by a PVT method at high temperature (1,600° C., under air, at 1 atm) and without intentionally using any sublimation activators.

The method is carried out in an oven with two areas equipped with heating elements in molybdenum disilicide capable of operating at temperatures ranging up to 1,700° C. under oxidizing conditions. The ZnO powder is placed in an alumina crucible, heated up to a temperature located between 1,650° C. and 1,680° C. for 1 hour, and is then maintained at this temperature for a duration of 5-10 hours under air at atmospheric pressure.

The configuration retained in document [11] is not a growth configuration, the result of the test is spontaneous germination of ZnO on the edges of the crucible. This does not correspond to controlled growth on a substrate. Further, there is no means for controlling the growth atmosphere which is air in all the cases.

Documents [12] and [13] describe a [symbol] CVT [symbol] method carried out between 900 and 1,100° C. The partial pressure of zinc is controlled by the temperature of the cold point. The ZnO source, as well as metal zinc in the presence of hydrogen, are placed in a quartz envelope, ampoule sealed in a temperature gradient.

Document [14] relates to the growth of ZnO by [symbol] CVT [symbol] by using CO₂ and Zn as transport agents.

ZnO powder and zinc powder are placed in quartz envelopes, ampoules which are heated in order to remove any trace of water in the Zn and ZnO source, and are then hermetically sealed under a residual pressure of CO₂ from 0.1 to 0.3 atm. No carbon, notably as graphite, is introduced into the ampoule but directly CO₂. CO which could for example result from the reaction of an oxidizing gas with carbon is not generated according to this document.

Document [15] describes bulk (solid) ZnO crystalline growth by a [symbol] CVT [symbol] method by using polyvinyl alcohol (PVA) as a transport agent. ZnO and PVA are placed in a closed envelope, ampoule with a crystalline ZnO seed.

The source is heated to 1,100° C. PVA decomposes into CO, CO₂ and H₂ which are used as transport agents.

No carbon notably as graphite is introduced into the envelope, ampoule. Hydrogen production is not an advantageous phenomenon since hydrogen has significant responsibility in the intrinsic n type doping of ZnO which generally is desirably avoided.

Document [16] relates to a method and an apparatus for preparing bulk (solid) aluminium nitride single crystals of large size. The apparatus comprises a heat source such as a radiofrequency coil which generates an electromagnetic field in the growth enclosure. This magnetic field is coupled with a metal susceptor formed by a sliding tube inside which the crucible, where the source material which is polycrystalline AIN and the seed are found, is placed.

The sublimation methods described in the aforementioned documents [5], [6], [7], [8], [9], [10], [11], [12], and [13] allow preparation of ZnO crystals in a quartz crucible at growth rates which may range up to 200 μm/h, but these crystals have higher defect densities than crystals prepared by hydrothermal growth processes.

Considering the foregoing, there therefore exists a need for a method with which ZnO single crystals of excellent structural quality may be prepared, with a reduced level of defects, free of impurities, of significant volume for example greater than 200 cm³, at a high growth rate for example above 200 μm/h.

Further there exists a need for such a method which is simple, reliable, easy to apply, carry out, notably when it is compared with methods under strong, high, pressure, and which includes a limited number of steps.

In other words, there exists a need for a method for growing ZnO single crystals with which it is both possible to elaborate notably the desired wurtzite ZnO phase with the required orientation for the application and to control the quality of the material, and which for microelectronics further allows single crystals to be prepared having a size of interest, i.e. generally with a diameter greater than 2″ and with a thickness generally greater than 5 mm.

To summarize, there exists a need for a method for preparing ZnO single crystals with which an optimum compromise may be achieved between the cost, the size of the obtained ZnO single crystals and the quality of the latter, while simultaneously obtaining the lowest cost and the greatest size and quality.

More specifically, there exists a need for a method for preparing, growing single crystals of zinc oxide, ZnO, by a sublimation and chemical vapor transport SCVT ( [symbol] Sublimation Chemical Vapor Transport [symbol] ) method which does not have the drawbacks of the methods described in documents [5], [6], [7], [8], [9], [10], [11], [12], [13] and (14], [15] and [16].

The goal of the invention is to provide a method for preparing ZnO polycrystals and single crystals which meet the whole of the needs, requirements and criteria listed above.

The goal of the invention is also to provide a method for preparing polycrystals and single crystals of ZnO which do not have the drawbacks, defects, limitations and disadvantages of the methods of the prior art and which solve the problems of the methods of the prior art.

Thus, with our invention, it is possible to get rid of the limitation of use of the silica tubes used in documents [6], [7], [8], [9], [10], [12], [13]. Indeed, the use of heating elements of the resistive type placed close to the silica envelope, ampoule limits the working temperatures to about 1,100° C. At these temperatures, silica softens and chemical reaction is activated with the gas species, in particular zinc.

Thus, with our invention it is possible to get rid of the limitation of use indicated in documents [5] and [11] which use alumina Al₂O₃ or Y₂O₃-stabilized ZrO₂ tubes which are also heated by MoSi₂ elements (resistive). With this system it is possible to attain higher temperatures around 1,650° C. [5]. But with this approach, it is not possible to work at too reduced oxygen pressures. For MoSi₂, the atmosphere should always remain an oxidizing atmosphere. The control of the atmosphere, not suggested in document [11], is operative in document [5]; on the other hand it imposes a non-sealed crucible required according to the author in order not to cause cracks in the crystal, due to thermal expansion coefficient differences between alumina and ZnO.

This goal and still other ones are achieved according to the invention by a method for preparing polycrystalline or single-crystal zinc oxide ZnO on a seed placed in an enclosure (chamber) under a controlled atmosphere, by sublimation of a zinc oxide source placed in a crucible inside the enclosure and distant from the seed, by forming gas species, transporting the gas species, condensing the gas species on the seed, recombining ZnO at the surface of the seed, growing polycrystalline or single-crystal ZnO on the seed, and cooling the polycrystalline or single-crystal ZnO, wherein:
the zinc oxide source is heated by induction to a temperature, a so-called sublimation temperature from 900 to 1,400° C. under a pressure from 2.10⁻³ atmospheres to 0.9 atmospheres;
CO is generated in situ as a sublimation activator by providing at least one oxidizing species, or a mixture of an oxidizing species and of at least one inert gas on a solid carbon source placed inside the enclosure;
and a control of the stoichiometry of ZnO is performed by achieving a localized supply with a controlled flow rate, for example in an amount from 1 SCCM (Standard Cubic Centimeters per Minute) to 100 SCCM, of at least one oxidizing species, or of a mixture of at least one oxidizing species and of at least one inert gas, in the vicinity of a growth interface of the ZnO.

The method according to the invention may be defined as a sublimation and chemical transport vapor phase method SCVT ( [symbol] Sublimation Chemical Vapor Transport [symbol] ) with which polycrystalline or monocrystalline ZnO crystals may be prepared, wherein the source for example, zinc oxide powder, is heated to a specific temperature from 900 to 1,400° C. and under a specific pressure of 2.10⁻³ atm to 0.9 atm, wherein the heating of the crucible and therefore of the zinc oxide source is carried out by induction and in which a supply, preferably a localized controlled supply of at least one oxidizing species, is provided on a solid carbon source such as graphite, and in the vicinity of a growth interface of the ZnO.

The method according to the invention is therefore fundamentally distinct from the methods of the prior art, and in particular from the PVT method described in document [5], by at least four fundamental features.

First of all, the method according to the invention uses inductive heating, and then the method according to the invention uses specific temperature and pressure ranges, i.e. respectively from 900 to 1,400° C. and from 2.10⁻³ atm to 0.9 atm which may really, actually be established simultaneously.

Next, the method according to the invention achieves a preferably controlled and localized supply of at least one oxidizing species not only on a solid carbon source, but also simultaneously in the vicinity of a growth interface of the ZnO.

It may be stated that according to the invention, a [symbol] SCVT [symbol] approach is applied, in which a supply of an oxidizing species is achieved, more specifically a flow of oxidizing species, notably of oxygen is controlled both on a solid carbon source such as purified graphite, and on a ZnO crystallization interface in order to control the stoichiometry of ZnO.

The method according to the invention which is a SCVT method thus notably differs from the method of document [5] which is a PVT method by the streams, flows of CO generated in situ, and of O₂. The method according to the invention also differs from the methods of the prior art, such as the one of document [5] or of document [15] by the fact that it specifically uses CO as a sublimation activator, as a carrier gas. Document [5] mentions H₂ or H₂O as a carrier gas but never CO.

By not using hydrogen as a carrier gas, all the disadvantages which are related to its use are avoided.

According to the invention, the sublimation activator gas is CO which will substantially increase the Zn and O₂ sublimation level of the ZnO source. A significant sublimation level will thereby be obtained which will allow a condensation rate allowing growth rates generally from 200 to 400 μm/h and up to 800 μm/h with an excellent compromise between the quality of the obtained crystal and the growth rate.

Heating by induction may either be internal or external to the enclosure under a controlled atmosphere.

More specifically, this heating by induction may be achieved by induction heating means comprising a susceptor placed in the enclosure in contact with the crucible and an inductor or one-turn induction coil.

The inductor may be located either inside the enclosure under a controlled atmosphere or outside the enclosure under a controlled atmosphere.

The inductor or one-turn induction coil [symbol] couples [symbol] to the susceptor which will thereby heat the crucible containing the ZnO source.

The susceptor is in a material selected from metals such as iridium, platinum or zirconium; or else in a particularly advantageous way, the susceptor is in graphite.

The materials used for the susceptor are of a nature different from that of the materials used in the prior art for similar devices.

The nature of the controlled atmosphere of course depends on the nature of the susceptor.

With the method according to the invention, which applies induction heating, it is possible to get rid of the limitations related to the use of silica tubes in documents [6], [7], [8], [9], [10], [12], [13]. Indeed, in these documents, the use of heating elements of the resistive type placed close to the silica ampoule limits the working temperatures to about 1,100° C. At these temperatures, silica softens and a chemical reaction is activated with the gas species, in particular zinc.

With the method according to the invention, it is also possible to get rid of the limitations related to the use, in documents [5] and [11], of alumina Al₂O₃ tubes or tubes in zirconia ZrO₂ stabilized by Y₂O₃, which are also heated by (resistive) MoSi₂ elements. With this system, higher temperatures, close to 1,650° C. [5], may be attained but it is not possible to work at too reduced oxygen pressures. Further for MoSi₂, the atmosphere should always remain an oxidizing atmosphere. Control of the atmosphere, not suggested in document [11], is applied in document [5], but it imposes an unsealed crucible, required according to the author for not causing cracks in the crystal, due to thermal expansion coefficient differences between alumina and ZnO.

The method according to the invention, and more particularly its growth phase, is carried out with in situ generation of a sublimation activator which is CO.

This in situ generation of a sublimation activator which is CO, is achieved by providing an oxidizing species or a mixture of an oxidizing species and of at least one neutral gas on a solid carbon source placed inside the enclosure.

This supply of an oxidizing species or of a mixture of at least one oxidizing species and of at least one neutral gas on a solid carbon source placed inside the enclosure may be achieved in different ways.

In a first embodiment, the solid carbon source is placed in a compartment defined inside the crucible, in order to separate the solid carbon source from the zinc oxide source; and a stream of at least one oxidizing species or of a mixture of at least one oxidizing species and of at least one inert gas is sent into said compartment.

Preferably, said stream of at least one oxidizing species or of a mixture of at least one oxidizing species and of at least one inert gas, is a stream localized on the solid carbon source and with a regulated, controlled, flow rate, for example in an amount from 1 SCCM to 100 SCCM.

In this embodiment, the solid carbon source advantageously appears in the form of one or more graphite blocks.

In a second embodiment, the solid carbon source consists in a graphite susceptor in contact with the crucible and the oxygen supply is achieved by establishing an oxidizing atmosphere inside the enclosure.

The second embodiment in which inductive heating is used with a graphite susceptor, will give the possibility of both having a heating means and ensuring easy production of CO.

In the first embodiment of the supply of the oxidizing species on the solid carbon source, the susceptor is preferably in metal, for example in platinum, iridium, zirconium; or in graphite. It is not required that the susceptor be in graphite.

According to the invention, control of the stoichiometry of ZnO is achieved by providing a localized supply of at least one oxidizing species or of a mixture of at least one oxidizing species and of at least one inert gas, in the vicinity of a growth interface, in other words, a localized supply of this oxidizing species or of this mixture is provided at the growth interface or close to the latter. This supply is provided with a controlled, regulated flow rate.

It should be noted that this supply of an oxidizing species or of a mixture is added in addition to the atmosphere which prevails inside the enclosure where growth takes place.

This oxidizing species may be selected from oxygen and ozone, and this inert gas may be selected from nitrogen, argon, helium, etc.

More specifically, the localized supply of at least one oxidizing species or of a mixture of at least one oxidizing species and of at least one inert gas in the vicinity of a growth interface, allows the stoichiometry of the ZnO to be very accurately controlled via the control of the partial oxygen pressure, in the vicinity, near, the growth interface, or on the latter.

The means with which the partial oxygen pressure and consequently the stoichiometry of ZnO may be controlled are generally constituted by a device called an [symbol] oxygen cell [symbol] , generally installed in the crucible containing the ZnO.

With this cell it is thereby possible to control the partial pressure close to the growth interface, both during the growth preparation phase, i.e. notably during the steps for raising the temperature and setting the working pressure, during the strictly speaking growth phase where the sublimation atmospheres and the atmosphere of the cell are shared in common, and finally during the cooling phase.

Preferably, the temperature to which is heated the source, for example the zinc oxide powder in the crucible, is from 1,100 to 1,200° C.

Preferably, the pressure at which the zinc oxide source is heated (2.10⁻³ to 0.9 atm), which is generally analogous to the pressure at which transport of the gas species is achieved, is from 0.1 to 0.5 atm and this pressure advantageously is a controlled, regulated pressure.

Advantageously, the temperature of the seed, or crystallization temperature, is set to 800° C.-1,200° C., preferably 1,000° C.-1,100° C.

The growth gradient, the difference between the sublimation temperature of the ZnO source and the crystallization temperature on the single crystal seed, is generally from 10° C. to 100° C./cm, preferably from 20° C./cm to 30° C./cm.

According to the invention, it was notably possible to achieve growth of a <0001>-oriented single crystal ZnO on a <0001>-oriented sapphire seed (heteroepitaxy) without any specific preparation by a sublimation and chemical vapor transport method [symbol] SCVT [symbol] (Sublimation Chemical Vapor Transport).

According to the invention, it was also notably possible to achieve growth (homoepitaxy) of <0001>-oriented single crystal ZnO on a <0001>-oriented ZnO seed (Zn or O surface polarity) with a specific preparation of the seed by a sublimation and chemical vapor transport method SCVT (Sublimation Chemical Vapor Transport).

With the specific temperature and pressure domains used according to the invention, it is possible to vary the average growth rates in a wide range generally comprised between 10 μm/h and 5 mm/h, preferably from 100 μm/h to 400 μm/h.

With the method according to the invention, it is thereby possible to attain growth rates which are clearly greater than the growth rates obtained with hydrothermal methods. These growth rates are obtained without deteriorating the quality of the obtained ZnO single crystals.

Thus, ZnO single crystals of good structural quality with a very low density of defects have been obtained.

The growth rates of the method according to the invention are attractive, may be adapted with the obtaining of a bulk (solid) material, i.e. for which the thickness is generally greater than 5 mm in order to be able to cut the ZnO ingot into substrates with a thickness from 300 to 600 μm.

With the method according to the invention, it is further possible to prepare crystals of [symbol] large [symbol] size i.e. generally from 5.08 cm (2″) to 10.16 cm (4″) and beyond, the size of the crystals depending on the size of the seed used, notably for applications in microelectronics.

The method according to the invention meets the needs listed above for a method for preparing ZnO single crystals, and it does have the drawbacks, defects of the methods, notably PVT methods, of the prior art such as the one described in document [5].

The method according to the invention, operating at low pressure and at high temperature, uses the successive transformations of the solid-gas-solid ZnO.

The method according to the invention is carried out under a controlled atmosphere. By controlled atmosphere is generally meant that this atmosphere has a composition and pressure perfectly under control at any instant of the method.

The method according to the invention may either be carried out in a reducing atmosphere, for example a H₂ atmosphere; or in an oxidizing atmosphere for example an O₂ atmosphere; or in a neutral atmosphere, for example an atmosphere of argon or nitrogen, or of a mixture of argon and nitrogen; or further in a mixed atmosphere, for example an atmosphere of a mixture of argon and oxygen or of a mixture of nitrogen and oxygen.

With a mixed atmosphere, for example Ar/N₂, generally with 5-40% of N₂ (by volume), a ZnO material of very high purity may be elaborated, and notably a ZnO material of type p may be obtained.

The zinc oxide source may either consist of zinc oxide powder (generally a [symbol] 5N [symbol] type high purity powder), or a ZnO granulate, or a ZnO ceramic.

If the source consists of zinc oxide powder, the average grain size of this zinc oxide powder is generally from 10 to 100 μm. Such a grain size allows proper sintering of the powder during the method.

The control of recovery on a seed is possible by controlling the decrease in pressure from the initial pressure (which is generally 1 atm) right down to the transport pressure inside the chamber and/or by controlling the temperature gradient between the powder/vapor and vapor/ZnO crystal surfaces at the transport pressure.

The method according to the invention ensures the growth of ZnO single crystals on very diverse seeds.

The seed may for example be selected from sapphire Al₂O₃ seeds oriented along (0001), (11-20), (1-100); ZnO seeds oriented along (0001), (000-1), (11-20), (1-100); 4H-SiC or 6H-SiC seeds oriented along (0001) (000-1), (11-20), (1-100); 3C-SiC seeds oriented along (100) or (111); GaN seeds oriented along (0001) (000-1), (11-20), (1-100); AlN seeds oriented along (0001) (000-1), (11-20), (1-100); magnesia spinels MgAl₂O₄.

The seed may be a single crystal.

A slight disorientation of the seeds mentioned earlier generally between 0 to 8° towards another remarkable crystallographic direction promotes 2D growth conditions for ZnO (growth by advancing crystallographic steps).

The crucible is generally a crucible in ceramic such as Al₂O₃, MgO, or ZrO₂, preferably said ceramic is porous.

An inner surface of the crucible may be covered with a coating of the same nature as the crucible or of a different nature.

The invention further relates to a device for carrying out the method described above comprising:
an enclosure, and means for maintaining said enclosure under a controlled atmosphere;
means in said enclosure, capable of receiving a seed;
a crucible inside said enclosure capable of receiving a source of zinc oxide so that it is distant from said seed;
a solid carbon source placed inside said enclosure;
means for heating said enclosure by induction;
means for providing a localized supply at a controlled flow rate of at least one oxidizing species or of at least one oxidizing species and of at least one inert gas, in the vicinity of a growth interface of the ZnO;
means for providing a supply of at least one oxidizing species or of a mixture of at least one oxidizing species and of at least one inert gas on said solid carbon source.

Advantageously, the means for heating the enclosure by induction may comprise a susceptor in contact with the crucible and an inductor.

According to a first embodiment, the solid carbon source may be placed in a compartment defined inside the crucible, said compartment separating the solid carbon source from the zinc oxide source, and means may be provided for sending a stream of at least one oxidizing species or of a mixture of at least one oxidizing species and of at least one inert gas into said compartment.

Advantageously, the means for sending a stream of at least one oxidizing species or of a mixture of at least one oxidizing species and of at least one inert gas into said compartment may be provided for supplying a localized stream on said carbon source and with a controlled flow rate.

Advantageously, the solid carbon source placed in said compartment may be in the form of one or more graphite blocks.

According to a second embodiment, the solid graphite source consists of a graphite susceptor, preferably in purified graphite, in contact with the crucible.

The invention will now be described in detail in the following description, given as an illustration and not as a limitation, with reference to the appended drawings, wherein:

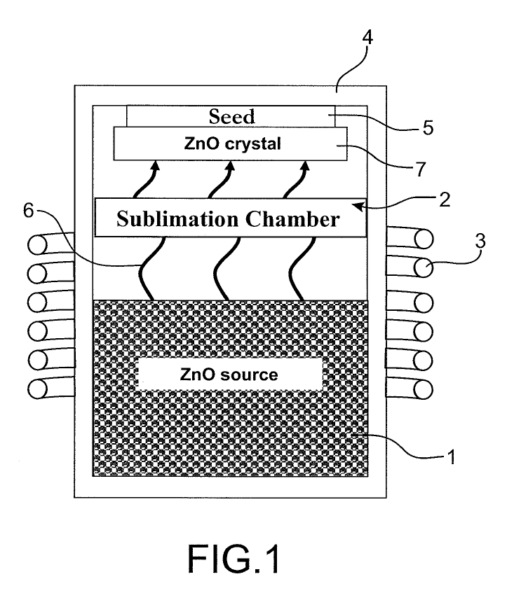

FIG. 1 is a schematic view which shows the principle of growing ZnO by sublimation;

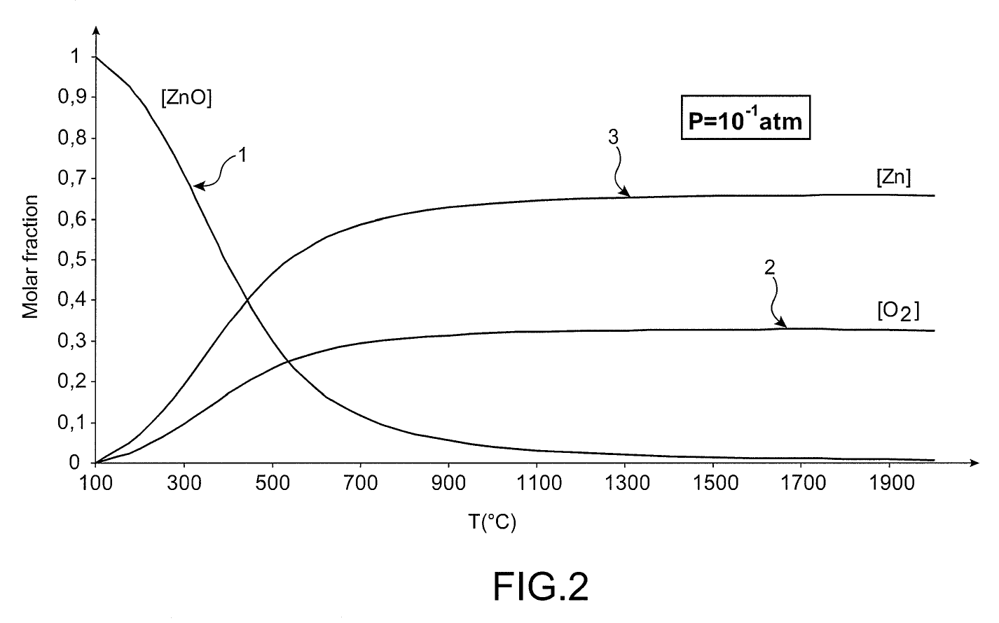

FIG. 2 is a calculated graph which gives the molar fraction versus the temperature T (° C.) of ZnO (curve (1)), of O₂ (curve (2)) and of Zn (curve (3)) at a total pressure of 10¹ atm;

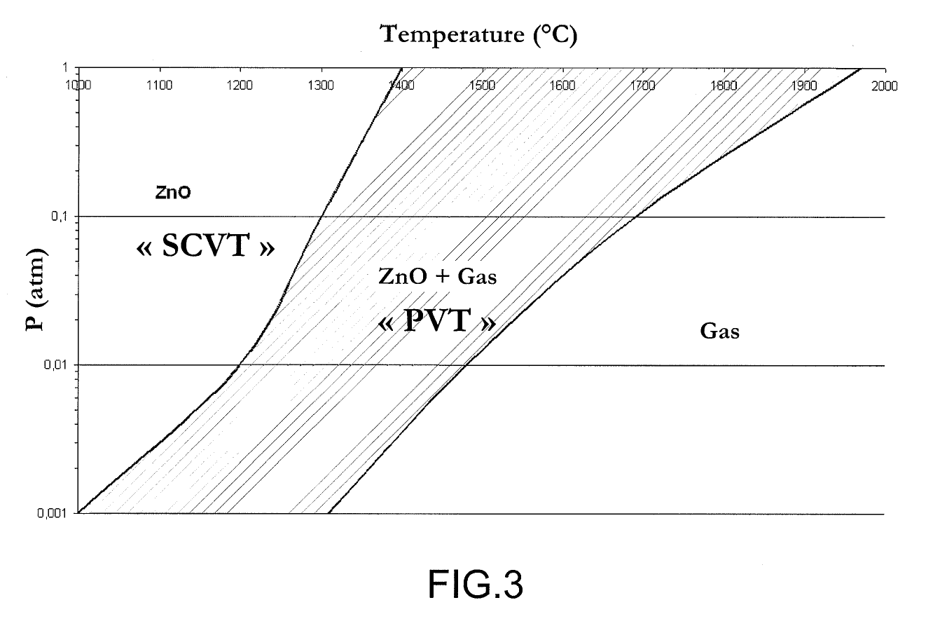

FIG. 3 is a calculated graph which illustrates the [symbol] SCVT [symbol] and [symbol] PVT [symbol] domains of ZnO in which there exists sufficient gas flow for allowing direct transport;

The total pressure in the sublimation chamber (in atm) is plotted in ordinates and the temperature and the temperature T (in ° C.) is plotted in abscissas;

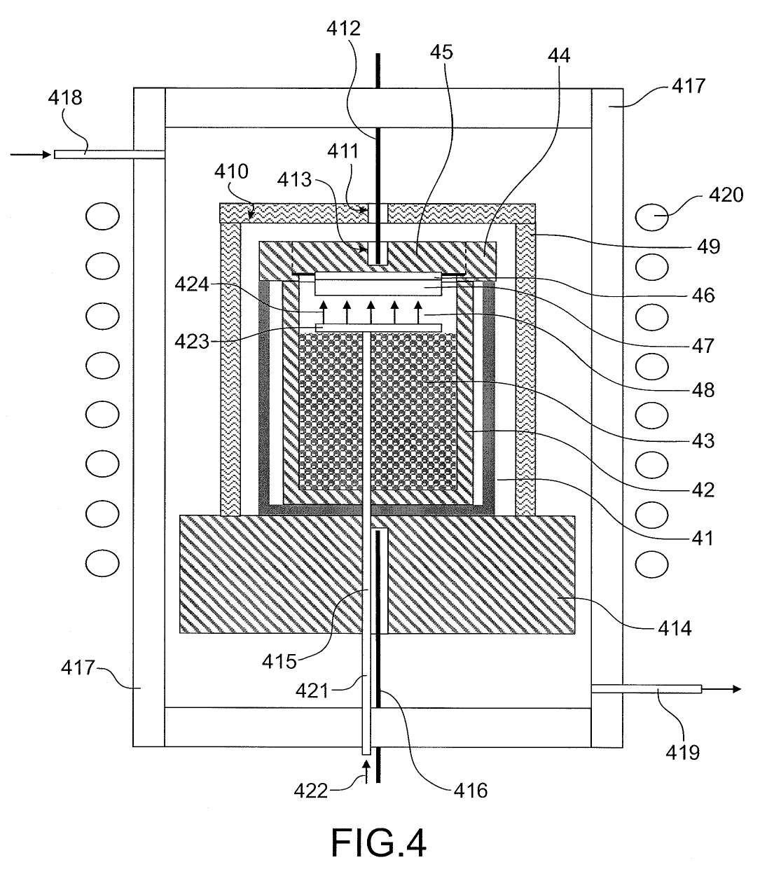

FIG. 4 is a schematic sectional view which illustrates a possible device for carrying out the method according to the invention including an [symbol] oxygen cell [symbol] ;

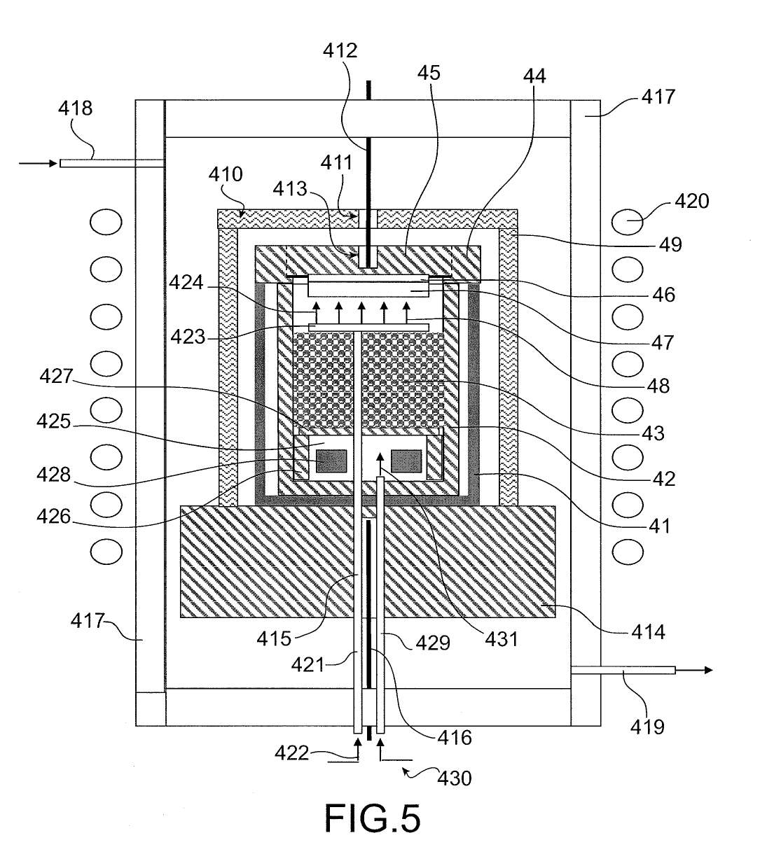

FIG. 5 is a schematic sectional view which illustrates a possible device for carrying out the method according to the invention including an [symbol] oxygen cell [symbol] and a [symbol] CO cell [symbol] ;

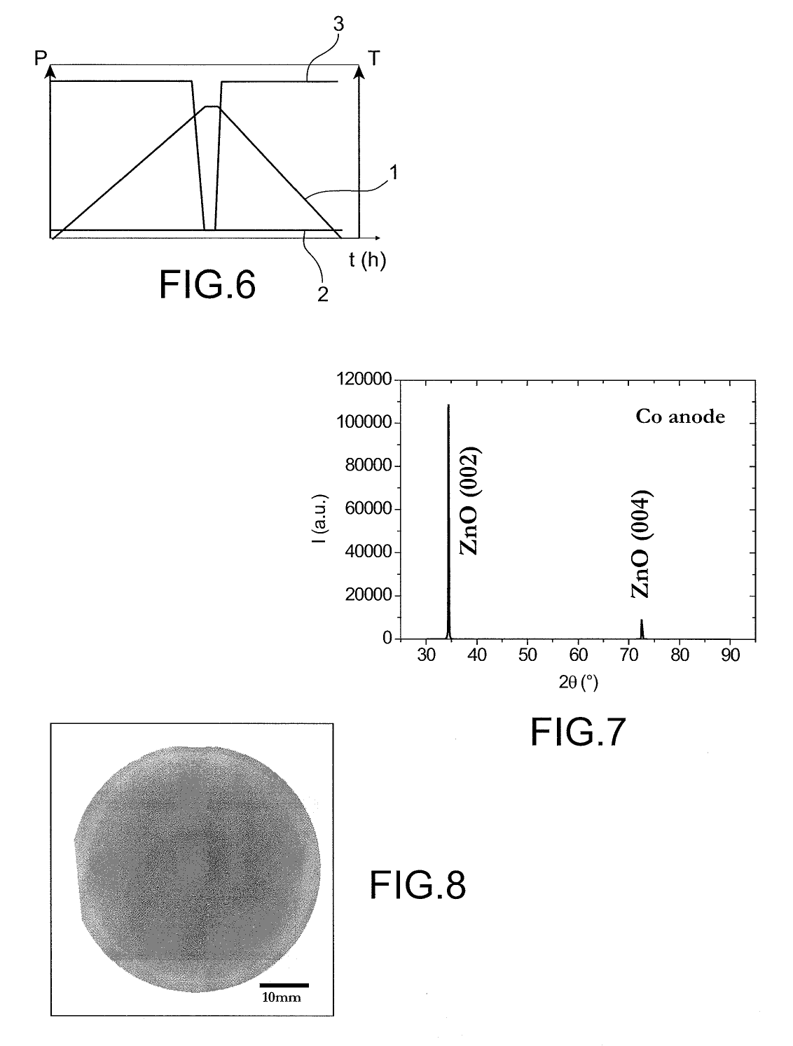

FIG. 6 is a graph which illustrates the different temperature profiles (curve \textcircled{1}) and pressure profiles (type 1: curve \textcircled{2} and type 2: curve \textcircled{3}) which may be used in the method according to the invention.

The time (hours) is plotted in abscissas and the pressure P (in atm) or the temperature T (in ° C.) is plotted in ordinates;

FIG. 7 is the X ray powder diffraction diagram (cobalt anode) of the ZnO obtained in the example.

The intensity I is plotted in ordinates in arbitrary units (a.u.) and the diffraction angle)2 θ(° is plotted in abscissas;

FIG. 8 is a photograph which shows the sample of ZnO on sapphire 2″ obtained in the example after polishing. The scale plotted on FIG. 8 represents 10 mm.

The schematic diagram of a method for growing ZnO by sublimation such as the one according to the invention is illustrated in FIG. 1.

A ZnO source, for example ZnO powder (1), generally deposited in a crucible (not shown) is placed in an enclosure or sublimation chamber (2) generally closed, not hermetically closed, and heated via a heating device consisting for example, in the case of the invention, of inductive coil turns (3).

At the top of this sublimation chamber, a crystallization seed (5) is positioned generally on the internal face of its upper wall or lid (4). The gas species containing zinc and oxygen, generated by the heating of the ZnO source, evaporate (6) in the sublimation chamber and will condense on the seed (5) in order to form a ZnO crystal (7).

The schematic diagram of the method of the invention is substantially similar to that of FIG. 1 but the method according to the invention is fundamentally characterized by the use of induction heating, by the use of specific temperatures and pressures as well as of complementary reactions between the gas species formed and the other materials which are at the origin of the advantages given by the method according to the invention.

It is known that the ZnO material has properties of dissociation of its solid phase into gas species during the rise in temperature at reduced pressure. The inventors have calculated and established the curves of FIG. 2 from thermodynamic simulations carried out in homogeneous chemistry with the software package [symbol] Thermosuite [symbol] . This curve shows the equilibrium partial pressures of the species Zn and O₂ with solid ZnO versus temperature T and pressure P.

These calculations were carried out within the scope of PVT, i.e. under a neutral argon atmosphere. First of all, they allow identification of the gas species in equilibrium with solid ZnO. It appears that at a [symbol] low [symbol] temperature and at a high pressure, (i.e. a temperature below 1,000° C. and under 1 atm), the majority species in contact with the solid is the ZnO gas (Equation 1):

<ZnO> [symbol] [ZnO] Equation 1

The partial pressure of this species is however very low, of the order of 10⁻¹⁰ atm, which makes bulk ZnO transport as a gas via this single vector unconceivable. On the other hand by operating according to the invention at a higher temperature and/or under a lower pressure, the equilibrium between solid <ZnO> and the gas phase is changed by the formation of gases [Zn] and [O₂] (Equation 2) :

$$〈 Zn O 〉 ⇔ [ Zn ] + \frac{1}{2} [ {O}_{2} ] \qquad Equation 2$$

These partial pressure values are quite comparable with those obtained for elaborating silicon carbide (T above 2,000° C., P less than 10⁻² atm), which is a positive element for the PVT approach applied to growth of ZnO.

A limitation is however provided by the existence of the sublimation equilibrium of <ZnO>which occurs between 1,400° C. and 1,950° C. for pressures comprised between 10⁻³ atm and 1 atm respectively, during which the partial pressures of [Zn] and [O₂] increase very strongly (see FIG. 3), which makes the PVT method difficult to control under these conditions.

In FIG. 3, the [symbol] SCVT [symbol] and [symbol] PVT [symbol] domains are illustrated, i.e. the temperature and pressure domains in which respectively, the sublimation reaction has to be activated by a chemical [symbol] SCVT [symbol] species, or else there exists a sufficient gas flow so that direct transport occurs.

According to the invention, one operates in the [symbol] SCVT [symbol] domain.

The results of these calculations of complex equilibriums are based on the validity of the available thermodynamic databases, data which are less accurate and complete than are those relating to silicon or silicon carbide for example, but the experimental tests conducted by the inventors have confirmed these results.

According to the invention, a supply of an oxidizing species is provided on a solid carbon source, either by using induction heating with coupling onto a graphite susceptor playing the role of this solid carbon source, and by maintaining an oxidizing atmosphere in the enclosure; or by sending a stream of oxidizing gas, preferably localized, with a controlled flow rate into a compartment of the crucible in which is found a solid carbon source, preferably as one or more graphite blocks.

An infinite source of graphite is therefore available which allows perfect control of the reaction defined by the following equation 3:

$$2 < C > + \frac{3}{2} [ {O}_{2} ] = [ CO ] + [ {CO}_{2} ] \qquad Equation 3$$

The initial sublimation reaction defined by equation 2 has a low contribution in the method according to the invention to the production of the Zn and O species. In the [symbol] SCVT [symbol] approach according to the invention, the majority reaction is the one defined by the following equation 4:

[CO]+<ZnO>=[Zn]+[CO₂] Equation 4

Thus, the sublimation rates are much greater than in the [symbol] PVT [symbol] of document [5]. One of the advantages of the method according to the invention is that it produces more species at a lower temperature (at equal pressure).

Further, close to the crystallization interface, zinc concentration is significant, and therefore according to the invention the yield of the condensation according to the following equation 2:

$$[ Zn ] + \frac{1}{2} [ {O}_{2} ] = < Zn O >$$

is increased by achieving a localized supply of additional oxygen which will significantly increase the condensation rate and allow control of the stoichiometry of the crystallization front of the ZnO crystal.

Further, all the reactions are subject to equilibria between them both at the sublimation interface and at the condensation interface and according to the invention, all these reaction systems have been completely quantified.

The method of the invention may be applied in any known PVT sublimation apparatus such as the one described in EP-A1-0 801 155 (U.S. Pat. No. 6,113,692), to the description of which reference may be made, by adapting the temperature and pressure conditions, by providing this apparatus with induction heating of the crucible, with an [symbol] oxygen cell [symbol] and with means allowing in situ production of CO inside the enclosure by supplying an oxidizing species such as oxygen on a solid carbon source such as graphite.

A device particularly suitable for carrying out the method according to the invention is described in FIG. 4. In this device, the solid carbon source consists of a graphite susceptor, preferably in purified graphite.

This device thus includes a susceptor (41) forming a container with a generally cylindrical shape comprising a sidewall and a bottom. This susceptor (41) receives, contains a crucible in dense ceramic, for example in Al₂O₃, MgO, or ZrO₂ (42), in which is placed the zinc oxide source, consisting of ZnO powder (43) for example. The crucible generally also has a cylindrical shape but with a smaller diameter than the susceptor.

The susceptor (41) in graphite is open at its upper end, and its sidewall has an upper edge on which lies the external circumference of an annular part (44) which is also supported by the top of the sidewalls of the crucible. This annular part therefore has an external diameter substantially equal to the diameter of the susceptor, and has an internal diameter substantially equal to the diameter of the crucible. This annular part is generally in the same material as the crucible, i.e. in dense ceramic, for example in Al₂O₃, MgO, or ZrO₂,

The annular part (44) includes on its internal circumference a shoulder on which is received a part (45) generally with the shape of a disc forming a lid. The part (45) is in a material generally identical with the material of the crucible, i.e. in dense ceramic, for example in Al₂O₃, MgO, or ZrO₂. This part thereby closes the upper end of the crucible (42) and forms the lid of the latter by bearing upon the shoulder of the annular ceramic part (44).

On the lower internal surface of the lid (45), thereby facing the surface of the ZnO source, is attached a substrate, seed (46) for example a <0001> sapphire with a size of generally 2 inches. It is on this substrate, seed (46), on which the ZnO crystal (47) grows.

A sublimation chamber or enclosure (48) is defined between the lower surface of the lid (45) or more exactly the lower surface of the seed, substrate (46), and the upper surface of the source, for example of the powder of ZnO (43).

The susceptor (41) is placed in an enclosure consisting in an insulating dense ceramic tube for example in Al₂O₃, MgO, or ZrO₂, (49) provided with a lid or crown (410) also in insulating dense ceramic, for example in Al₂O₃, MgO, or ZrO₂. The lid (410) is crossed by a bore (411) for letting through a thermocouple (412), called “upper” thermocouple ending up into a cavity (413) of the lid (45). This thermocouple (412) allows measurement of the temperature in the vicinity of the seed (46).

The susceptor (41) and the tube (49) lie on a support (414) generally in ceramic of the Al₂O₃, MgO, ZrO₂ type in which a bore (415) is provided, intended for providing a passage for a thermocouple (416) (generally in its centre), a so-called [symbol] lower thermocouple [symbol] such as a PtRh—Pt thermocouple. This thermocouple allows measurement of the temperature in the vicinity of the susceptor.

The tube (49) provided with its lid (410), placed on the support (414) is itself installed in an electrically insulating silica enclosure (417), and the space between the silica enclosure (417) and the ceramic tube (49) is generally filled with insulating ceramic (wool) based e.g. on Al₂O₃.

The enclosure (417) according to the invention has means for maintaining said enclosure under a controlled atmosphere. These means may thereby comprise a system for producing a primary and secondary vacuum, as well as means for sending a stream, flow of gas into the enclosure (417) and for discharging a stream, flow of gas from the enclosure (417), for example in the form of supply and discharge conduits passing through the enclosure (418, 419). The enclosure may also be provided with devices for controlling the flow of gas for example argon, nitrogen, oxygen, ozone, N₂O, H₂, CO, and for controlling the pressure (not shown).

The heating of the susceptor (41) is achieved in FIG. 4, and according to the invention by inductive coil turns (420) for example located outside the silica enclosure (417), and surrounding the latter. These inductive coil turns are generally cooled by continuous circulation of water.

Indeed, because of the temperature range targeted in the method of the invention which is from 900 to 1,400° C., inductive heating is required.

As this has already been specified above, in the case of the device of FIG. 4, the susceptor which is used is in graphite, and the working atmosphere is notably a neutral gas—argon for example—, or a very slightly oxidizing gas (formation of CO). The use of a graphite susceptor in the [symbol] SCVT [symbol] domain of FIG. 3, because the crucible is not completely sealed, will generate secondary reactions between the oxygen and the hot graphite (equation 3), and then a reaction between the zinc oxide and the carbon monoxide (equation 4):

$$\begin{matrix}2 < C > + \frac{3}{2} [ {O}_{2} ] = [ CO ] + [ {CO}_{2} ] & Equation 3 \\ [ CO ] + < Zn O >= [ Zn ] + [ {CO}_{2} ] & Equation 4\end{matrix}$$

The oxygen involved in the reaction illustrated by equation 3 stems from the decomposition of ZnO according to equation 1, from the excess oxygen stemming from the [symbol] oxygen cell [symbol] (see below) and optionally from the flow feeding the enclosure (418).

The graphite susceptor will in this case play the role of an “infinite” solid carbon source, in addition to its initial role of a heating element, which is particularly advantageous.

By [symbol] unsealed [symbol] , “not tight”, crucible, is meant that the crucible may be porous but this porosity is not mandatory. Indeed the assemblies of the ceramics in the enclosure are not sealed, tight. A seal, tightness is not sought, and it is ensured that the assemblies are not sealed, tight, and that pressure equilibrium is established inside the enclosure.

The sublimation of the ZnO source is thus chemically activated by CO and allows crystallization of the ZnO on the seed with a growth rate comprised between 200 and 800 μm/h. This reaction approach is substantiated by experimental observations: slight etching of the graphite, formation of zinc on the external cold portions, continuous increase in the pressure in its regulation interval.

The thereby formed ZnO crystal is in this case transparent and slightly yellow-orange, a sign of a stoichiometric lack of oxygen.

The proposed solution for providing a remedy to this problem consists, according to the invention, of providing means for achieving a localized supply with a controlled flow rate of at least one oxidizing species or of at least one oxidizing species and of at least one inert gas in the vicinity of the growth interface of the ZnO. Thus, a supply of at least one oxidizing species such as oxygen, or of a mixture of at least one oxidizing species and of at least one inert gas may be added, this supply being localized close to the growth interface. This device called an [symbol] oxygen cell [symbol] is also illustrated in FIG. 4.

It comprises a conduit (421) for supplying an oxidizing gas (422) such as oxygen or ozone, or a mixture of an oxidizing gas and of an inert gas such as nitrogen, which crosses, goes through, the base of the enclosure (417), the support (414), and the bases of the susceptor (41) and of the crucible (42) in order to feed a distribution ramp (423), located in the crucible near the seed, in the vicinity of the surface where growth occurs, and for thereby providing a stream (424) of oxidizing gas or of a mixture of oxidizing gas and of an inert gas near or at the growth interface.

With the [symbol] oxygen cell [symbol] device, it is possible to slightly shift the equilibrium of the reaction of equation 2 to the oxygen-rich side.

For the insulating materials used in the device of the invention, notably the material in direct contact with the ZnO used for confining ZnO in the crucible, oxides of the type MgO and ZrO₂ according to the invention have been preferred.

Alumina and sapphire should generally be avoided since in direct contact with ZnO they form a spinel ZnAl₂O₄.

It should be noted that the system, not completely sealed, tight, from the start, may become quasi-sealed, quasi-tight, after [symbol] sealing [symbol] the crucible (42) with the seed-holder lid (45), the binder being the deposit of crystallized ZnO on the edges of the crucible (42). This phenomenon depends on temperature and pressure conditions within the crucible.

Under these conditions when the crucible becomes sealed, tight a too large loss of raw material is avoided and the system either operates under thermodynamic equilibrium conditions at the vapor phase level (pressure and gas species) or with slight oxygen excess with the [symbol] oxygen cell [symbol] .

FIG. 5 illustrates another device particularly suitable for carrying out the method according to the invention. The device is substantially analogous to the one of FIG. 4 but in this device, the solid carbon source is placed in a compartment defined in the crucible.

The device of FIG. 5 thus further comprises a compartment or chamber (425), defined in the lower portion of the crucible. This compartment or chamber (425) is formed by an annular part (426) in contact with the sidewall of the crucible, and on which lies a lid (427). The zinc oxide source (43), consisting for example of ZnO powder, is placed on the lid (427).

A solid carbon source generally consisting in one or more purified graphite blocks (428) is placed in this compartment or chamber (425). This (these) block(s) thereby form(s) a reserve of graphite and has(have) a size generally from 0.5 to 1 cm³.

The device of FIG. 5 further comprises means for sending a stream of at least one oxidizing species or of a mixture of at least one oxidizing species and of at least one inert gas into said compartment. These means may comprise, as illustrated in FIG. 5, a duct for supplying (429) an oxidizing gas (430), such as oxygen or ozone, or a mixture of an oxidizing gas and of an inert gas such as nitrogen, which crosses, goes through, the base of the enclosure (417), the support (414), and the basis of the susceptor (41) and of the crucible (42) in order to open out into the compartment or chamber, and thereby provide a stream (431) of oxidizing gas or of a mixture of oxidizing gas and of inert gas onto the graphite block(s) (428). This stream is generally a localized stream, i.e. it is accurately directed onto the surface of the block(s), for example by bringing the conduit as close as possible to the blocks, and regulated, monitored, controlled, in the sense that its flow rate is regulated, adjusted, monitored, controlled by means such as valves, mass flowmeters, and regulation devices (not shown) known to one skilled in the art.

In the device of FIG. 5, the susceptor is not mandatorily in graphite as in FIG. 4.

The susceptor used in the device of FIG. 5 may be a platinum susceptor which is the best choice of thermochemical compatibility for a metal, or else a susceptor in iridium which has better resistance to temperature but with which there is a possibility of oxidation of the susceptor under an oxidizing atmosphere and a degradation of the latter at too reduced pressure.

According to the invention, various temperature and pressure profiles may be used which are illustrated in FIG. 6:
either after a degassing cycle in a secondary vacuum at a cold and/or low temperature, the desired working pressure is set and the working temperature is gradually raised.

In this first case after the degassing step, the working pressure is set for example between 10⁻³ atm and 1 atm (pressure of type 1, curve \textcircled{2} in

FIG. 6) and then the temperature is raised gradually (curve (1) in FIG. 6) with rates for example comprised between 150 and 400° C./h right up to the desired sublimation temperature for the ZnO powder (between 900 and 1,400° C.). This temperature is maintained during the duration of the plateau i.e. during the desired transport time for example 1 to 20 hours, and then the temperature is lowered with rates comprised between 150 and 400° C./h down to room temperature,
or a strong (high) pressure is set, for example 1 atm (a so-called blocking pressure i.e. above the equilibrium pressure of the species at the working temperature), and the working temperature is raised with rates comprised between 150 and 400° C./h up to the desired sublimation temperature for the ZnO powder (between 1,200 and 1,500° C.), and then the pressure is lowered very gradually down to the desired set pressure value for the sublimation test, for example between 10⁻³ atm and 1 atm (pressure of type 2, curve \textcircled{3} in FIG. 6).

The invention will now be described with reference to the following example given as an illustration and not as a limitation.

### EXAMPLE

In this example, by carrying out the method of the invention, growth of ZnO is achieved on a sapphire substrate from KYOCERA® (for example) with a size of 2 inches and oriented along c(0001).

The device used is the one described in FIG. 4.

ZnO powder 5N from NEYCO® or CERAC® with a grain size from 10 to 100 μm is placed in the graphite crucible.

The sublimation temperature ranges from 1,350 to 1,370° C., while the crystallization temperature at the seed ranges from 1,150 to 1,200° C.

The working temperature is 10⁻² atm, the latter is set according to the approach of type 2 as described earlier.

Under these conditions, a single crystal of ZnO oriented along the direction c(0001) was formed on the sapphire seed as this is demonstrated in the X ray powder diffraction diagram of FIG. 7 where peaks of ZnO (002) and (004) are clearly observed.

The sample obtained in this example should then undergo a polishing treatment for example.

FIG. 8 is a photograph of the ZnO sample on sapphire after polishing.

Thus, the average growth rate is 500 μm/h.

### REFERENCES

[1] U.S. Pat. No. 5,900,600
[2] U.S. Pat. No. 6,936,101
[3] US-A1-2006/0124051
[4] DE-A1-10 2004003596
[5] U.S. Pat. No. B1-7,279,040 dated Oct. 9, 2007.
[6] J.-M. Ntep, Mr. Barbé, G. Cohen-Solal, F. Bailly, A. Lusson, R. Triboulet. ZnO growth by chemically assisted Sublimation. Journal of Crystal Growth 184-185 (1998) 1026-1030.
[7] J.-M. Ntep, S. Said Hassani, A. Lusson, A. Tromson-Carli, D. Ballutaud, G. Didier, R. Triboulet. ZnO growth by chemical vapour transport. Journal of Crystal Growth 207 (1999) 30-34.
[8] Makoto Mikami, Takashi Sato, JiFeng Wang, Yoshohiko Masa, Minoru Isshiki. Growth of zinc oxide by chemical vapour transport. Journal of Crystal Growth 276 (2005) 389-392.
[9] Makoto Mikami, Takashi Sato, JiFeng Wang, Yoshohiko Masa, Minoru Isshiki. Improved reproductibility in zinc oxide single crystal growth by chemical vapor transport. Journal of Crystal Growth 286 (2006) 213-217.
[10] R. Tena-Zaera, M. C. Martinez-Toma, S. Hassani, R. Triboulet, V. Munoz-Sanjosé. Study of the ZnO crystal growth by vapor transport methods. Journal of Crystal Growth 270 (2004) 711-721.
[11] J. Carlos Rojo, Shanshan Liang, Hui Chen, Michael Dudley. Physical vapor transport crystal growth of ZnO. Proceedings of SPIE, Vol. 6122 (2006).
[12] Krzysztof. Grasza, Andrezej Mycielski. Contactless CVT growth of ZnO crystals. Physica Status Soilidi (c) 2, No. 3, 1115-1118 (2005).
[13] K. Grasza, A. Mycielski, J. Domagala, V. Domukhovski, W. Paszkowicz, H. Sarkoska, W. Hofman. ZnO crystals for substrates in micro and optoelectronic applications. Physica Status Soilidi (c) 3, No. 4, 793-796 (2006).
[14] M. MIKAMI et al. Growth of ZnO by chemical vapor transport using CO₂ and Zn as a transport agent. Journal of Crystal Growth 304 (2007), 37-41.
[15] H. UDONO et al. Crystal Growth of ZnO bulk by CUT method using PVA. Journal of Crystal Growth 310 (2008), 1827-1831.
[16] WO-A2-2004/061896.

1. A method for preparing polycrystalline or single-crystal zinc oxide ZnO on a seed placed in an enclosure under a controlled atmosphere, by sublimation of a zinc oxide source placed in a crucible inside the enclosure and distant from the seed, by forming the gas species, transporting the gas species, condensing the gas species on the seed, recombinating the ZnO at the surface of the seed, growth of polycrystalline or single-crystal ZnO on the seed, and cooling of the polycrystalline or single-crystal ZnO, the method comprising:
heating the zinc oxide source by induction to a temperature, a so-called sublimation temperature from 900 to 1,400° C. under a pressure of 2.10⁻³ atmospheres to 0.9 atmospheres;
generating CO in situ as a sublimation activator by providing at least one oxidizing species, or a mixture of at least one oxidizing species and of at least one inert gas, on a solid carbon source placed inside the enclosure; and
controlling the stoichiometry of ZnO by achieving a localized supply with a controlled flow rate in an amount from 1 SCCM to 100 SCCM, of at least one oxidizing species, or of a mixture of at least one oxidizing species and of at least one inert gas, in the vicinity of a growth interface of the ZnO.

2. The method according to claim 1, wherein the induction heating is achieved by induction heating means comprising a susceptor, placed in the enclosure, in contact with the crucible and an inductor.

3. The method according to claim 2, wherein the inductor is located either inside or outside the enclosure under a controlled atmosphere.

4. The method according to claim 2, wherein the susceptor is in a material selected from metals comprising iridium, platinum and zirconium; and graphite.

5. The method according to claim 1,
wherein the solid carbon source is placed in a compartment defined inside the crucible to separate the solid carbon source from the zinc oxide source, and a stream of at least one oxidizing species or of a mixture of at least one oxidizing species and of at least one inert gas is sent into said compartment.

6. The method according to claim 5,
wherein said stream of at least one oxidizing species, or of a mixture of at least one oxidizing species and of at least one inert gas, is a stream localized on said solid carbon source, and which has a controlled flow rate in an amount from 1 SCCM to 100 SCCM.

7. The method according to claim 5, wherein the solid carbon source is in the form of one or more graphite blocks.

8. The method according to claim 1, wherein the solid carbon source consists in a graphite susceptor in contact with the crucible, and the supply of at least one oxidizing species is achieved by establishing an oxidizing atmosphere inside the enclosure.

9. The method according to claim 1, wherein the oxidizing species is selected from oxygen and ozone, and the inert gas is selected from nitrogen, argon and helium.

10. The method according to claim 1, wherein the zinc oxide source is heated to a temperature of 1,100 to 1,200° C.

11. The method according to claim 1, wherein the transport of the gas species is achieved under a pressure from 0.1 to 0.5 atm.

12. The method according to claim 1, wherein the temperature of the seed, said crystallization temperature, is from 800 to 1,200° C.

13. The method according to claim 1, wherein the difference between the sublimation temperature and the crystallization temperature is from 10 to 100° C./cm.

14. The method according to claim 1, wherein the single-crystal zinc oxide grows on the seed at a rate of 10 μm/h to 5 mm/h.

15. The method according to claim 1, wherein the zinc oxide source is zinc oxide powder, ZnO granulate, or ZnO ceramic.

16. The method according to claim 15, wherein the zinc oxide powder is [symbol] 5N [symbol] type high purity powder.

17. The method according to claim 15, wherein the zinc oxide powder has an average grain size from 10 to 100 μm.

18. The method according to claim 1, wherein the seed is selected from sapphire Al₂O₃ seeds oriented along (0001), (11-20), (1-100); ZnO seeds oriented along (0001), (000-1), (11-20), (1-100); 4H-SiC or 6H-SiC seeds oriented along (0001) (000-1), (11-20), (1-100); 3C-SiC seeds oriented along (100) or (111); GaN seeds oriented along (0001) (000-1), (11-20), (1-100); AlN seeds oriented along (0001) (000-1), (11-20), (1-100); magnesia spinels MgAl₂O₄.

19. The method according to claim 18, wherein the seeds are disoriented from 0 to 8° towards another remarkable crystallographic direction.

20. The method according to claim 1, wherein the seed is a single crystal.

21. The method according to claim 1, wherein the method is carried in a reducing atmosphere such as an H₂ atmosphere; an oxidizing atmosphere such as an O₂ atmosphere; a neutral atmosphere such as an atmosphere of argon, or nitrogen, or of a mixture of argon and nitrogen; or a mixed atmosphere such as an atmosphere of a mixture of argon and oxygen or a mixture of nitrogen and oxygen.

22. The method according to claim 21, wherein the method is carried out in an argon and nitrogen atmosphere comprising 5 to 40% of nitrogen by volume.

23. The method according to claim 1, wherein the crucible is a crucible in ceramic such as Al₂O₃, MgO, or ZrO₂, and said ceramic is porous.

24. The method according to claim 1, wherein an inner surface of the crucible is covered with a coating of the same nature as the crucible or of different nature.

25. A device for carrying out the method according to claim 1, the device comprising:
an enclosure, and means for maintaining said enclosure under a controlled atmosphere;
means in said enclosure, capable of receiving a seed;
a crucible inside said enclosure capable of receiving a zinc oxide source so that it is distant from said seed;
a solid carbon source placed inside said enclosure;
means for heating said enclosure by induction;
means for providing a localized supply with a controlled flow rate of at least one oxidizing species or of at least one oxidizing species and of at least one inert gas in the vicinity of a growth interface of the ZnO; and
means for providing a supply of at least one oxidizing species or of a mixture of at least one oxidizing species and of at least one inert gas on said solid carbon source.

26. The device according to claim 25, wherein the means for heating the enclosure by induction comprises a susceptor in contact with the crucible and an inductor.

27. The device according to claim 25, wherein the solid carbon source is placed in a compartment defined inside the crucible, said compartment separating the solid carbon source from the zinc oxide source, and means are provided for sending a stream of at least one oxidizing species or of a mixture of at least one oxidizing species and of at least one inert gas into said compartment).

28. The device according to claim 27 wherein the means for sending a stream of at least one oxidizing species or of a mixture of at least one oxidizing species and of at least one inert gas into said compartment, are provided for supplying a localized stream on said carbon source and with a controlled flow rate.

29. The device according to claim 27, wherein the carbon source is in the form of one or more graphite blocks.

30. The device according to claim 26, wherein the solid graphite source comprises a graphite susceptor in contact with the crucible.

31. The device according to claim 27, wherein the solid graphite source comprises graphite susceptor in contact with the crucible.

32. The method according to claim 12, wherein the temperature of the seed, said crystallization temperature, is from 1,000 to 1,100° C.

33. The method according to claim 13, wherein the difference between the sublimation temperature and the crystallization temperature is from 20° C./cm to 30° C./cm.

34. The method according to claim 14, wherein the single-crystal zinc oxide grows on the seed at a rate of from 100 μm/h to 400 μm/h.
